(19) United States
(12) Patent Application Publication
(10) Pub. No.: US 2026/0337774 A1
(43) Pub. Date: Oct. 29, 2026

(54) METHOD FOR FORMING SILICON OXIDE FILM

(71) Applicants: AIR WATER INC., Osaka-shi, Osaka (JP); AIR WATER PERFORMANCE CHEMICAL INC., Kawasaki-shi, Kanagawa (JP)

(72) Inventors: Koichi FUKUI, Hiratsuka-shi, Kanagawa (JP); Keisuke NAGATA, Matsumoto-shi, Nagano (JP); Hiroshi SHIBANO, Matsumoto-shi, Nagano (JP)

(21) Appl. No.: 19/142,770

(22) PCT Filed: Dec. 27, 2023
(86) PCT No.: PCT/JP2023/047013

§ 371 Date: Jun. 24, 2025

(30) Foreign Application Priority Data
Dec. 28, 2022 (JP) 2022211212

(51) Int. Cl. C23C 16/455; C01B 33/18; C23C 16/04; C23C 16/40; C23C 16/44; H10P 14/60; H10P 14/692

(52) U.S. Cl. CPC C23C 16/45553; C01B 33/183; C23C 16/045; C23C 16/401; C23C 16/4408; H10P 14/6339; H10P 14/6681; H10P 14/69215

(57) ABSTRACT

A method for forming a silicon oxide film includes: a provision step of providing a substrate in a reactor; a first introduction step of introducing, into the reactor, at least one silicon compound represented by Formula (1); a first purge step of purging the reactor with purge gas; a second introduction step of introducing an oxygen source into the reactor; and a second purge step of purging the reactor with the purge gas, in which the first introduction step, the first purge step, the second introduction step, and the second purge step are performed repeatedly until silicon oxide having a desired thickness is deposited on a surface of the substrate, and an average roughness of the thickness of the silicon oxide film is 10% or less with respect to the thickness of the silicon oxide film.

### TECHNICAL FIELD

The present disclosure relates to a method for forming a silicon oxide film.

### BACKGROUND ART

With the recent emergence of 3D NAND flash memory cells, film deposition of silicon oxide at high temperature (650° C. or more) has become required for forming high-quality insulating films having high adhesion and satisfactory coatability.

Chemical vapor deposition (CVD) has been mainly applied as a method for forming films of silicon oxide at high temperature. Unfortunately, CVD is not suitable for depositing films having high adhesion and satisfactory coatability since CVD is a method for depositing films using chemical reaction and pyrolysis. Since CVD does not enable film deposition on fine patterns, CVD cannot be adopted for fine portions.

Accordingly, formation of a silicon oxide film by atomic layer deposition (ALD) that enables high-quality film deposition in a high temperature range has been studied (for example, PTLs 1 and 2).

### CITATION LIST

### Patent Literature

PTL 1: Japanese Patent No. 6262702
PTL 2: WO2021/050368

### SUMMARY OF INVENTION

### Technical Problem

The present disclosure is directed to providing a method for forming, by atomic layer deposition, a silicon oxide film with a highly uniform thickness from a silicon compound having high heat resistance.

### Solution to Problem

[1]A method for forming a silicon oxide film includes:
a provision step of providing a substrate in a reactor;
a first introduction step of introducing, into the reactor, at least one silicon compound represented by the following Formula (1);
a first purge step of purging the reactor with purge gas;
a second introduction step of introducing an oxygen source into the reactor; and
a second purge step of purging the reactor with the purge gas, wherein
the first introduction step, the first purge step, the second introduction step, and the second purge step are performed repeatedly until silicon oxide having a desired thickness is deposited on a surface of the substrate,
the first introduction step, the first purge step, the second introduction step, and the second purge step are performed at a temperature of 300° C. or more and 800° C. or less and a pressure of 7.6 Pa or more and 100 kPa or less, and
an average roughness of the thickness of the silicon oxide film thus formed is 10% or less with respect to the thickness of the silicon oxide film thus formed:

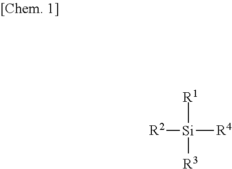

in the Formula (1),
   R¹ and R² are each independently a methyl group or an ethyl group,
   R³ is a methyl group, an ethyl group, a group represented by the following Formula (2), or a group represented by the following Formula (3), and
   R⁴ is a group represented by the following Formula (2), or a group represented by the following Formula (3):

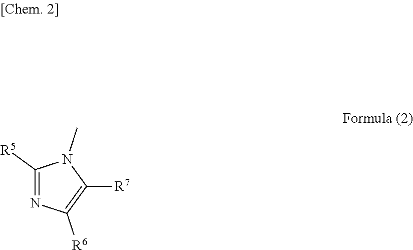

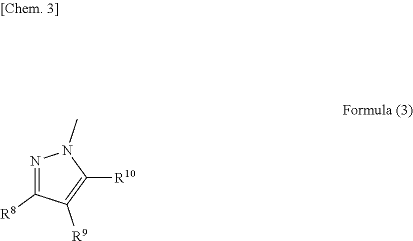

in the Formula (2) and the Formula (3), R⁵ to R¹⁰ are each independently a hydrogen atom, a methyl group, or an ethyl group.

[2]A method for forming a silicon oxide film includes:
a provision step of providing, in a reactor, a substrate having a surface provided with a groove;
a first introduction step of introducing, into the reactor, at least one silicon compound represented by the following Formula (1);
a first purge step of purging the reactor with purge gas;
a second introduction step of introducing an oxygen source into the reactor; and
a second purge step of purging the reactor with the purge gas, wherein
the first introduction step, the first purge step, the second introduction step, and the second purge step are performed repeatedly until silicon oxide having a desired thickness is deposited on the surface of the substrate,
the first introduction step, the first purge step, the second introduction step, and the second purge step are performed at a temperature of 300° C. or more and 800° C. or less and a pressure of 7.6 Pa or more and 100 kPa or less, and
the silicon oxide film satisfies a relationship defined by Formula (i):

|t₁−t₂|/t₁≤0.2
in the Formula (i),
   t₁ represents a thickness of the silicon oxide film (nm) in an upper portion of the groove, and
   t₂ represents a thickness of the silicon oxide film (nm) in a lower portion of the groove:

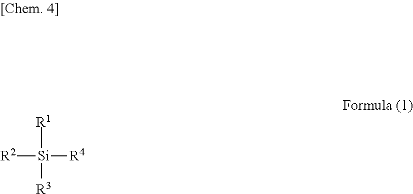

in the Formula (1),
   R¹ and R² are each independently a methyl group or an ethyl group,
   R³ is a methyl group, an ethyl group, a group represented by the following Formula (2), or a group represented by the following Formula (3), and
   R⁴ is a group represented by the following Formula (2), or a group represented by the following Formula (3):

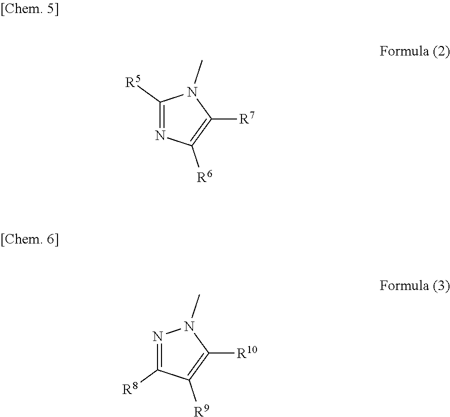

in the Formula (2) and the Formula (3), R⁵ to R¹⁰ are each independently a hydrogen atom, a methyl group, or an ethyl group.

[3] The method for forming a silicon oxide film according to [1] or [2], wherein
in the Formula (1),
   R¹ and R² are each a methyl group,
   R³ is a methyl group, or a group represented by the Formula (3), and
   R⁴ is a group represented by the Formula (3),
   where R⁸ to R¹⁰ are each independently a hydrogen atom, a methyl group, or an ethyl group.

[4] The method for forming a silicon oxide film according to [1] or [2], wherein
in the Formula (1),
   R¹ to R³ are each a methyl group, and
   R⁴ is a group represented by the Formula (3),
   where R⁸ to R¹⁰ are each a hydrogen atom.

[5] The method for forming a silicon oxide film according to [1] or [2], wherein
in the Formula (1),
   R¹ and R² are each a methyl group, and
   R³ and R⁴ are each a group represented by the Formula (2),
   where R⁵ to R⁷ are each independently a hydrogen atom, a methyl group, or an ethyl group.

[6] The method for forming a silicon oxide film according to [1] or [2], wherein
in the Formula (1),
   R¹ to R³ are each a methyl group, and
   R⁴ is a group represented by the Formula (2),
   where R⁵ to R⁷ are each a hydrogen atom.

### Advantageous Effects of Invention

The present disclosure enables providing a method for forming, by atomic layer deposition, a silicon oxide film with a highly uniform thickness from a silicon compound having high heat resistance.

### BRIEF DESCRIPTION OF DRAWINGS

FIG. 1 is a schematic flowchart of a method for forming a silicon oxide film in the present disclosure.

FIG. 2 is a conceptual diagram showing an example of a silicon oxide film formed on a substrate in Embodiment 1.

FIG. 3 is a conceptual diagram showing an example of a film deposition apparatus applicable to the method for forming a silicon oxide film in the present disclosure.

FIG. 4 is a conceptual diagram showing an example of a substrate in Embodiment 2.

FIG. 5 is a conceptual diagram showing an example of a silicon oxide film formed on the substrate in Embodiment 2.

FIG. 6 shows a graph illustrating a relationship of the rate of growth of a silicon oxide film, to the amount of a silicon compound fed, for each of respective silicon compounds of No. 1 and No. 2 in Test Example 1.

FIG. 7 shows a graph illustrating a relationship of the rate of growth of a silicon oxide film, to the film deposition temperature, for each of No. 1 and No. 2 in Test Example 2.

FIG. 8 shows photographs illustrating respective thicknesses of a silicon oxide film in (a) an upper portion, (b) an intermediate portion, and (c) a lower portion of a groove in a substrate in Test Example 3.

### DESCRIPTION OF EMBODIMENTS

Hereinafter, embodiments of the present disclosure are described. The following description, however, does not limit the scope of claims.

### Embodiment 1

### <Method for Forming Silicon Oxide Film>

A method for forming a silicon oxide film in the present embodiment includes a provision step of providing a substrate in a reactor, a first introduction step of introducing, into the reactor, at least one silicon compound represented by the following Formula (1), a first purge step of purging the reactor with purge gas, a second introduction step of introducing an oxygen source into the reactor, and a second purge step of purging the reactor with the purge gas. The first introduction step, the first purge step, the second introduction step, and the second purge step are performed repeatedly until silicon oxide having a desired thickness is deposited on a surface of the substrate. The first introduction step, the first purge step, the second introduction step, and the second purge step are performed at a temperature of 300° C. or more and 800° C. or less and a pressure of 7.6 Pa or more and 100 kPa or less. An average roughness of the thickness of the silicon oxide film thus formed is 10% or less with respect to the thickness of the silicon oxide film thus formed.

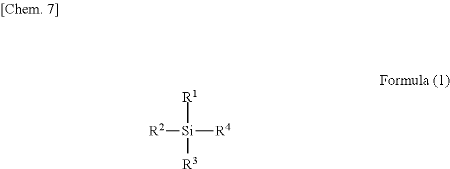

In the Formula (1), R¹ and R² are each independently a methyl group or an ethyl group, R³ is a methyl group, an ethyl group, a group represented by the following Formula (2), or a group represented by the following Formula (3), and R⁴ is a group represented by the following Formula (2), or a group represented by the following Formula (3).

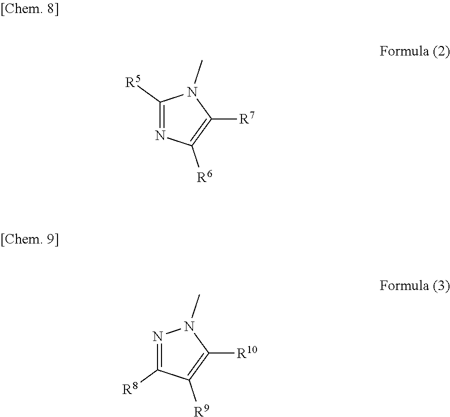

In the Formula (2) and the Formula (3), R⁵ to R¹⁰ are each independently a hydrogen atom, a methyl group, or an ethyl group.

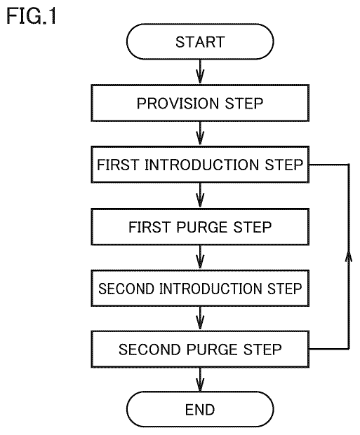

FIG. 1 is a schematic flowchart of a method for forming a silicon oxide film in the present embodiment. Hereinafter, each of the steps of the method for forming a silicon oxide film is described.

ALD includes two types of ALD, i.e., thermal ALD and plasma ALD. The present disclosure uses thermal ALD, which enables high-quality film deposition in a high temperature range.

### (Provision Step)

In the provision step, the substrate is provided in the reactor.

As long as the substrate used for the present disclosure enables the silicon compound serving as a precursor to grow on the substrate, the substrate is not particularly limited, and examples of the substrate include ceramic substrates such as a silicon substrate, a silicon oxide substrate, and a silicon nitride substrate. Among these, a silicon substrate or a silicon oxide substrate is preferably used from the viewpoint of high-quality film deposition.

A barrier film may be formed in advance on the substrate. Examples of the barrier film include titanium nitride and tantalum nitride.

### (First Introduction Step)

In the first introduction step, at least one silicon compound represented by the Formula (1) is introduced into the reactor. In this step, the silicon compound as the precursor is adsorbed on the substrate.

The silicon compound may be introduced into the reactor with carrier gas. The carrier gas as used herein refers to inert gas that promotes feeding of the silicon compound into the reactor. The carrier gas is not reacted with the silicon compound. Examples of the carrier gas include hydrogen (H₂), helium (He), nitrogen (N₂), neon (Ne), and Argon (Ar).

In the Formula (1), R¹ and R² are each independently a methyl group or an ethyl group, R³ is a methyl group, an ethyl group, a group represented by the Formula (2), or a group represented by the Formula (3), and R⁴ is a group represented by the Formula (2), or a group represented by the Formula (3).

Such a compound can serve as a useful precursor in the formation of a silicon oxide film. Examples of the silicon compound represented by the Formula (1) include a structure represented by the following Formula (4).

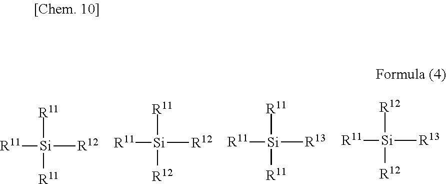

In the Formula (4), R¹¹ is a methyl group or an ethyl group, R¹² is any one of the structures represented by the following Formula (5), and R¹³ is any one of the structures represented by the following Formula (6). R¹¹ in the following Formula (5) and Formula (6) is the same group as the above-described one.

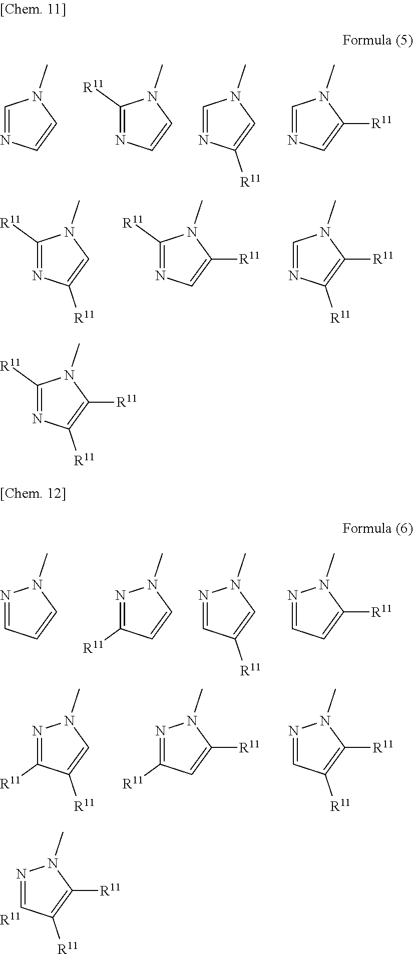

The silicon compound represented by the Formula (1) is preferably the silicon compound having the structure represented by the following Formula (7), and more preferably the silicon compound represented by the following formula (8), from the viewpoint of heat resistance and film deposition.

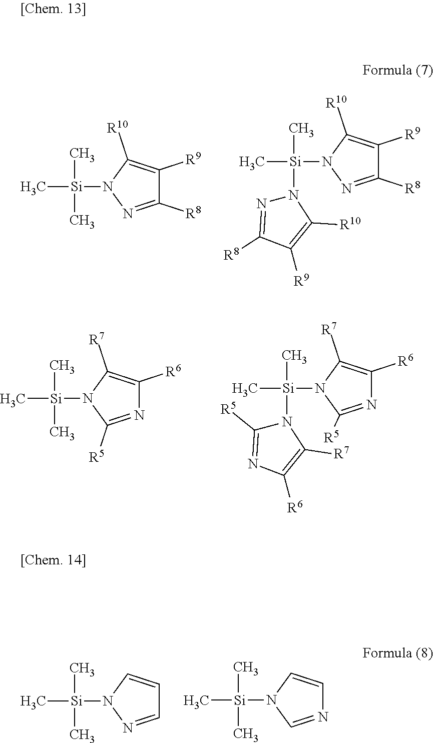

This step only has to be performed at a sufficient flow rate for a sufficient time to enable adsorbing the silicon compound on the substrate. This step may be performed, for example, for 0.1 seconds or more and 1000 seconds or less. The silicon compound in this step may be introduced into the reactor at a flow rate of 1 sccm or more and 2000 sccm or less, for example. The unit “sccm (standard cubic centimeter per minute)” of the flow rate is identical to “mL/min” under the standard conditions (0° C. and 101.3 kPa).

### (First Purge Step)

In the first purge step, the reactor after the first introduction step is purged with purge gas. This step is a step of removing an excess silicon compound not adsorbed on the substrate in the first introduction step.

As the purge gas, inert gas can be used that enables removing the silicon compound as the precursor. The purge gas is not reacted with the silicon compound. Examples of the purge gas that is such inert gas include the same gases as those indicated above as examples of the carrier gas.

This step only has to be performed at a sufficient flow rate for a sufficient time to enable removing an excess silicon compound. This step may be performed, for example, for 0.1 seconds or more and 1000 seconds or less. The purge gas in this step may be introduced into the reactor at a flow rate of 10 sccm or more and 2000 sccm or less, for example.

In this step, vacuum purging may be performed before purging the reactor with the purge gas. The vacuum purging may be performed, for example, for 0.1 seconds or more and 1000 seconds or less.

This step may be performed multiple times. In the case where the step is performed multiple times, the step may be repeated multiple times under the same or different conditions including the time for which the step is performed, and the flow rate and the purge gas used in the step. The vacuum purging may be performed between repetitions of the step. For example, purging with purge gas, vacuum purging, and purging with purge gas may be performed in this order.

### (Second Introduction Step)

In the second introduction step, the oxygen source is introduced into the reactor. This step is a step of reacting the silicon compound as the precursor adsorbed on the substrate with the oxygen source to form the silicon oxide film.

Examples of the oxygen source include, but not particularly limited to, water, oxygen (O₂), peroxides, oxygen plasma, ozone (O₃), nitrogen monoxide (N₂O), nitrogen dioxide (NO₂), carbon monoxide (CO), carbon dioxide (CO₂), and combinations thereof.

This step only has to be performed at a sufficient flow rate for a sufficient time to enable reacting the silicon compound with the oxygen source. This step may be performed, for example, for 0.1 seconds or more and 100 seconds or less. The oxygen source in this step may be introduced into the reactor at a flow rate of 1 sccm or more and 2000 sccm or less, for example.

### (Second Purge Step)

In the second purge step, the reactor after the second introduction step is purged with the purge gas. This step is a step of removing the oxygen source not reacted with the silicon compound in the second introduction step.

Since the purge gas used in this step, the time for which this step is performed, and the flow rate of the purge gas in this step are identical to those in the first purge step, details thereof are not herein repeated.

In this step, vacuum purging may be performed before purging the reactor with the purge gas. The vacuum purging may be performed, for example, for 0.1 seconds or more and 1000 seconds or less.

This step may be performed multiple times. In the case where the step is performed multiple times, the step may be repeated multiple times under the same or different conditions including the time for which the step is performed, and the flow rate and the purge gas used in the step. The vacuum purging may be performed between repetitions of the step.

(from First Introduction Step to Second Purge Step)

The first introduction step, the first purge step, the second introduction step, and the second purge step are performed at a temperature of 300° C. or more and 800° C. or less. If the first introduction step, the first purge step, the second introduction step, and the second purge step are performed at a temperature of 300° C. or more and 800° C. or less, a film can be deposited having high adhesion and satisfactory coatability. The first introduction step, the first purge step, the second introduction step, and the second purge step are preferably performed at a temperature of 500° C. or more and 750° C. or less, and more preferably performed at a temperature of 650° C. or more and 750° C. or less.

The first introduction step, the first purge step, the second introduction step, and the second purge step are performed at a pressure of 7.6 Pa or more and 100 kPa or less. If the first introduction step, the first purge step, the second introduction step, and the second purge step are performed at a pressure of 7.6 Pa or more and 100 kPa or less, a film can be deposited having high adhesion and satisfactory coatability. The first introduction step, the first purge step, the second introduction step, and the second purge step are preferably performed at a pressure of 10 Pa or more and 1 kPa or less.

The first introduction step, the first purge step, the second introduction step, and the second purge step are performed repeatedly. The first introduction step, the first purge step, the second introduction step, and the second purge step can be performed repeatedly to obtain a silicon oxide film having a desired thickness.

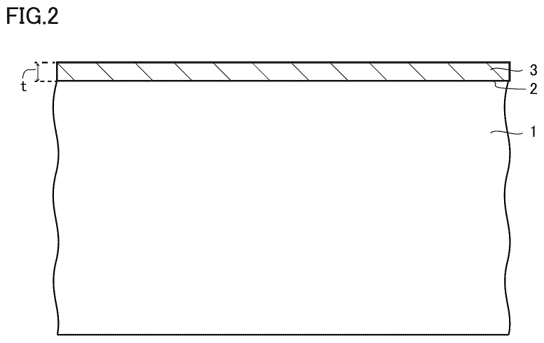

FIG. 2 is a conceptual diagram showing an example of the silicon oxide film formed on the substrate in the present embodiment. The thickness of silicon oxide film 3 in the present application refers to the thickness (“t” in FIG. 2) (nm) of silicon oxide film 3 deposited on a surface 2 of substrate 1. The desired thickness is, for example, 0.1 nm to 100 nm, and preferably 3 nm to 50 nm.

The thickness of silicon oxide film 3 deposited on surface 2 of substrate 1 is measured by X-ray reflectometry (XRR). The thickness of silicon oxide film 3 is measured by means of an X-ray reflectance measurement apparatus (XRR measurement apparatus) under, for example, the following conditions.

### [Conditions]

X-ray source: CuKα radiation
Power: 45 kv, 40 mA
Range of measurement: 0 to 6° C.
Step width: 0.002 mm
Scan rate: 0.05°/min

In the present embodiment, the average roughness (Ra) of the thickness of silicon oxide film 3 thus formed is 10% or less with respect to the thickness of silicon oxide film 3 thus formed. Ra is measured by XRR, similar to the one used for measuring the thickness of silicon oxide film 3. The smaller the value of Ra, the smaller the unevenness of the thickness of silicon oxide film 3, i.e., the higher the uniformity of the film thickness. Ra is preferably 5% or less, more preferably 3% or less, and still more preferably 1% or less.

### <Film Deposition Apparatus>

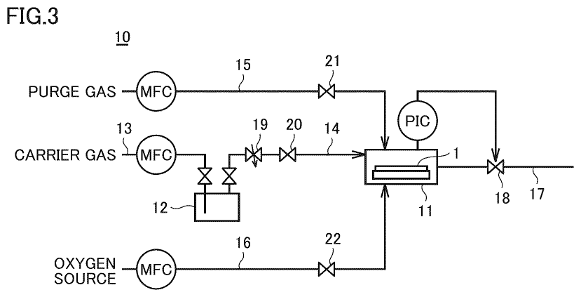

With reference to FIG. 3, an example of a film deposition apparatus applicable to the method for forming a silicon oxide film in the present embodiment is described. A film deposition apparatus 10 includes at least a reactor 11 for containing substrate 1 as an object to be treated, a precursor gas feed channel 14 for feeding a silicon compound as a precursor, a purge gas feed channel 15 for feeding purge gas, an oxygen source feed channel 16 for feeding an oxygen source, and a discharge channel 17 for discharging the atmosphere in reactor 11.

Reactor 11 has a hermetically sealed structure, which enables isolating the contents therein from the open air. Reactor 11 is configured to be able to contain substrate 1 maintained in a horizontal posture, for example, with help of a boat.

Reactor 11 may include a heating mechanism (not shown) that can heat substrate 1 contained therein to a predetermined temperature. Examples of the heating mechanism that can be adopted include, but not particularly limited to, known heating mechanisms such as heater.

A precursor feeder 12 has the function of feeding the precursor to reactor 11. Precursor feeder 12 stores the precursor in a liquid or solid state. A carrier gas feed channel 13 for introducing carrier gas is connected to precursor feeder 12. The flow rate of the carrier gas to be fed from carrier gas feed channel 13 can be controlled with an MFC (mass flow controller).

Precursor gas feed channel 14 is disposed between precursor feeder 12 and reactor 11. The liquid or solid precursor stored in precursor feeder 12 is gasified into precursor gas, which is fed to reactor 11. Precursor gas feed channel 14 is provided with a needle valve 19 and an on-off valve 20. Needle valve 19 regulates the flow rate of the gas flowing through precursor gas feed channel 14. On-off valve 20 controls feeding or stop of the gas flowing through precursor gas feed channel 14.

Purge gas feed channel 15 has the function of feeding the purge gas to reactor 11. Purge gas feed channel 15 is connected to reactor 11. The flow rate of the purge gas to be fed can be controlled with an MFC. Purge gas feed channel 15 is provided with an on-off valve 21. On-off valve 21 controls feeding or stop of the purge gas flowing through purge gas feed channel 15.

Oxygen source feed channel 16 has the function of feeding the oxygen source to reactor 11. Oxygen source feed channel 16 is connected to reactor 11. The flow rate of the oxygen source to be fed can be controlled with an MFC. Oxygen source feed channel 16 is provided with an on-off valve 22. On-off valve 22 controls feeding or stop of the oxygen source flowing through oxygen source feed channel 16.

Discharge channel 17 has the function of discharging the atmosphere in reactor 11. Discharge channel 17 is connected to reactor 11. Discharge channel 17 is connected to a pressure sensor (not shown) as a pressure detector for detecting the pressure in reactor 11, an APC (automatic pressure control valve) valve 18 as a pressure controller for controlling the pressure in reactor 11, and a vacuum pump (not shown) as an evacuation device. The opening/closing of APC valve 18 is regulated by PID (proportional-integral-differential controller) control based on measurement by the pressure sensor with the vacuum pump being operated. The pressure in reactor 11 is spontaneously regulated thereby.

The discharged gas from discharge channel 17 may contain, for example, toxic gas or flammable gas. Discharge channel 17 may therefore be provided, for example, with a water scrubber, a sulfuric acid scrubber, a caustic scrubber, or a dry detoxification device to make the discharged gas nontoxic and releasable to the atmosphere.

### Embodiment 2

### <Method for Forming Silicon Oxide Film>

A method for forming a silicon oxide film in the present embodiment includes a provision step of providing, in a reactor, a substrate having a surface provided with a groove, a first introduction step of introducing, into the reactor, at least one silicon compound represented by the following Formula (1), a first purge step of purging the reactor with purge gas, a second introduction step of introducing an oxygen source into the reactor, and a second purge step of purging the reactor with the purge gas. The first introduction step, the first purge step, the second introduction step, and the second purge step are performed repeatedly until silicon oxide having a desired thickness is deposited on the surface of the substrate. The first introduction step, the first purge step, the second introduction step, and the second purge step are performed at a temperature of 300° C. or more and 800° C. or less and a pressure of 7.6 Pa or more and 100 kPa or less. The silicon oxide film satisfies a relationship defined by the following Formula (i).

Formula (i):|t₁−t₂|/t₁≤0.2 Formula (i)

In the Formula (i), t₁ represents a thickness of the silicon oxide film (nm) in an upper portion of the groove, and t₂ represents a thickness of the silicon oxide film (nm) in a lower portion of the groove.

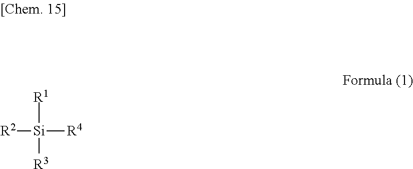

In the Formula (1), R¹ and R² are each independently a methyl group or an ethyl group, R³ is a methyl group, an ethyl group, a group represented by the following Formula (2), or a group represented by the following Formula (3), and R⁴ is a group represented by the following Formula (2), or a group represented by the following Formula (3).

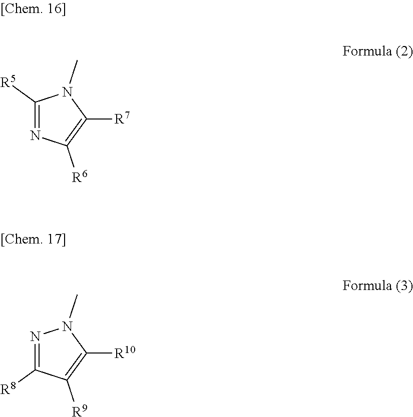

In the Formula (2) and the Formula (3), R⁵ to R¹⁰ are each independently a hydrogen atom, a methyl group, or an ethyl group.

Hereinafter, the method for forming a silicon oxide film in the present embodiment is described. The same description as that of Embodiment 1 is not herein repeated.

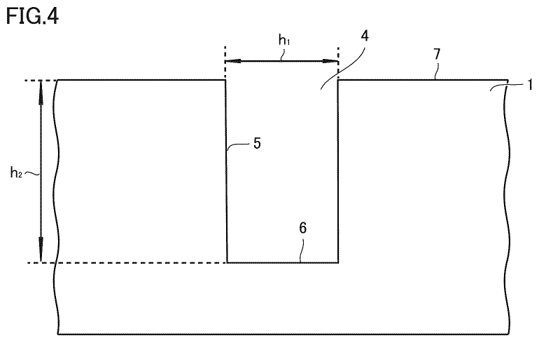

FIG. 4 is a conceptual diagram showing an example of the substrate in the present embodiment. Substrate 1 may include a surface 7 provided with a groove 4.

Groove 4 has a sidewall surface 5 and a bottom wall surface 6. Examples of groove 4 include hole, via, trench, and contact. One groove 4 may be provided in surface 7 of substrate 1, or a plurality of grooves 4 may be provided therein.

The width (“h₁” in FIG. 4) of groove 4 is, for example, 10 nm or more and 500 nm or less. The depth (“h₂” in FIG. 4) of groove 4 is, for example, 100 nm or more and 10 μm or less.

The ratio of the depth of groove 4 to the width of groove 4 (hereinafter referred to “aspect ratio”) may for example be 10 or more, 20 or more, or 50 or more. The aspect ratio may for example be 1000 or less, 500 or less, or 100 or less.

In the case where a plurality of grooves 4 are provided, these grooves 4 may be identical to or different from each other, in terms of the width, the depth, and the aspect ratio.

In the first introduction step, the silicon compound as a precursor is also caused to be adsorbed on groove 4. The present embodiment is similar to Embodiment 1 in other respects. The present embodiment is also similar to Embodiment 1 in terms of the first purge step, the second introduction step, and the second purge step.

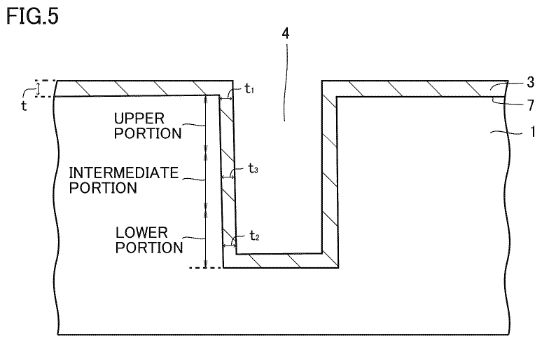

FIG. 5 is a conceptual diagram showing an example of the silicon oxide film formed on the substrate in the present embodiment. The thickness of silicon oxide film 3 deposited on surface 7 of substrate 1 is calculated in a similar manner to Embodiment 1. The thickness of silicon oxide film 3 deposited on groove 4 is calculated, for example, in the following manner. Specifically, the substrate is cut at any position in the direction perpendicular to groove 4, and subjected to focused ion beam (FIB) treatment. After the FIB treatment, a cross section is imaged by a transmission electron microscope (TEM). Conditions for the TEM are as follows. The resultant TEM image is binarized to distinguish substrate 1 and silicon oxide film 3 from each other. The binarization is performed with a threshold value that enables substrate 1 and silicon oxide film 3 to be appropriately distinguished from each other. From the TEM image, the thickness of silicon oxide film 3 is calculated. The arithmetic mean of the thickness of silicon oxide film 3 measured from a plurality of images may be regarded as the thickness of silicon oxide film 3.

### [Conditions for TEM]

Magnification: 750,000×
Accelerating voltage: 200 kV
Magnification accuracy: ±10%

In the present embodiment, the formed silicon oxide film 3 satisfies a relationship defined by the following Formula (i).

|t₁−t₂|/t₁≤0.2 Formula(i)

In the Formula (i), t₁ represents the thickness (nm) of silicon oxide film 3 in an upper portion of groove 4, and t₂ represents the thickness (nm) of silicon oxide film 3 in a lower portion of groove 4. The smaller the value of the Formula (i), the smaller the film thickness difference between the upper portion and the lower portion of groove 4 and thus the higher the film thickness uniformity. |t₁−t₂|/t₁ may be 0.15 or less, 0.10 or less, 0.05 or less, or 0.01 or less. |t₁−t₂|/t₁ is preferably 0.10 or less, more preferably 0.05 or less, and still more preferably 0.01 or less.

t₁ and t₂ are preferably almost equal to t, from the viewpoint of uniformity of the thickness of silicon oxide film 3, and more preferably equal to t.

In the present embodiment, the upper portion of groove 4 refers to the uppermost region among three equal regions into which groove 4 is divided in the depth direction, and the lower portion of groove 4 refers to the lowermost region among the three equal regions into which groove 4 is divided in the depth direction. t₁ may be the thickness measured in a portion or region away from surface 7 of substrate 1 by a certain distance. t₂ may be the thickness measured in a portion or region away from bottom wall surface 6 of groove 4 by a certain distance.

In the present embodiment, preferably the formed silicon oxide film 3 satisfies the following Formula (ii).

|t₁−t₃|/t₁≤0.2 Formula (ii)

In the Formula (ii), t₃ represents the thickness (nm) of silicon oxide film 3 in an intermediate portion of groove 4. The smaller the value of the Formula (ii), the smaller the film thickness difference between the upper portion and the intermediate portion of groove 4 and thus the higher the film thickness uniformity. |t₁−t₃/t₁ may be 0.15 or less, 0.10 or less, 0.05 or less, or 0.01 or less. |t₁−t₃|/t₁ is preferably 0.10 or less, more preferably 0.05 or less, and still more preferably 0.01 or less.

t₃ is preferably almost equal to t, from the viewpoint of uniformity of the thickness of silicon oxide film 3, and more preferably equal to t.

In the present embodiment, the intermediate portion of groove 4 refers to the intermediate region among three equal regions into which groove 4 is divided in the depth direction. t₃ may be the thickness measured in a portion or region away from surface 7 of substrate 1 by a certain distance.

In the present embodiment, preferably the formed silicon oxide film 3 satisfies a relationship defined by the following Formula (iii).

|t₂−t₃|/t₂≤0.2 Formula (iii)

The smaller the value of the Formula (iii), the smaller the film thickness difference between the upper portion and the intermediate portion of groove 4 and thus the higher the film thickness uniformity. |t₂−t₃|/t₂ may be 0.15 or less, 0.10 or less, 0.05 or less, or 0.01 or less. |t₂−t₃|/t₂ is preferably 0.1 or less, more preferably 0.05 or less, and still more preferably 0.01 or less.

t₁, t₂, and t₃ are measured in the same manner as the manner of measurement by means of the TEM as described above.

### EXAMPLES

Hereinafter, examples are described. The following examples, however, do not limit the scope of claims.

### <Apparatuses>

In the present example, apparatuses indicated below were used. Gas chromatograph is abbreviated as “GC” and gas chromatograph mass spectrometer is abbreviated as “GC-MS.” In the present example, a film deposition apparatus having the configuration shown in FIG. 3 was used.
GC: GC-2025AF manufactured by Shimadzu Corporation
GC-MS: MSQP2020NX manufactured by Shimadzu Corporation
TEM: H-9500 manufactured by Hitachi High-Tech Corporation
XRR measurement apparatus: X'Pert PRO manufactured by Malvern Panalytical Ltd.

### <Reagents>

In the present example, reagents indicated below were used. N-Trimethylsilylimidazole is abbreviated as “TMS-imidazole.”
Pyrazole: Manufactured by Tokyo Chemical Industry (TCI) Co., Ltd.
Ammonium sulfate: Manufactured by Hayashi Pure Chemical Ind., Ltd.
Hexamethyldisilazane: Manufactured by TCI Co., Ltd.
TMS-imidazole: Manufactured by TCI Co., Ltd.

### <Silicon Compound>

In the present example, trimethylsilyl pyrazole (abbreviated as “TMS-pyrazole” hereinafter) and TMS-imidazole expressed by the above-indicated Formula (8) were used. TMS-pyrazole was prepared in the following manner. TMS-pyrazole is referred to herein as compound “No. 1” and TMS-imidazole is referred to herein as compound “No. 2.”

### (Preparation)

51.5 g of pyrazole and a tiny amount of ammonium sulfate were added to a flask bottom and dried under vacuum. Thereafter, 62.0 g of hexamethyldisilazane was added, and reflux was performed under reflux conditions in a nitrogen atmosphere for 12 hours. The mixture after being refluxed was passed through a filter to collect a resultant liquid in light yellow. Thereafter, the obtained liquid was distilled under reduced pressure and thereby purified in a glovebox. Through analysis by the above-indicated GC-MS, it was confirmed that the resultant product was TMS-pyrazole. Through analysis by the above-indicated GC, it was confirmed that the purity was 99.0%.

### (Minimum Bond Dissociation Energy)

The minimum bond dissociation energy (MBDE) of the prepared TMS-pyrazole and TMS-imidazole was calculated. MBDE refers to the minimum value of BDE that is energy required to break a specific chemical bond, corresponds to the BDE of the weakest bond in a certain molecule and, the higher the value of the energy, the higher the heat resistance. The MBDE was determined by Gaussian 16, which is a quantum chemistry calculation program produced by Gaussian, Inc. The bond dissociation energy of a bond between silicon and a methyl group bonded to the silicon was MBDE. The results are shown in Table 1.

TABLE 1

| | No. 1 | No. 2 |
|---|---|---|
| MBDE (kJ/mol) | 384 | 377 |

It is seen from Table 1 that the MBDE of each of TMS-pyrazole and TMS-imidazole has a high value. It is accordingly seen that TMS-pyrazole and TMS-imidazole have high heat resistance.

### Test Example 1

Silicon oxide films were deposited from the prepared TMS-pyrazole and TMS-imidazole by atomic layer deposition. Specifically, a silicon substrate was placed as a substrate in the reactor of the film deposition apparatus as described above. The substrate was flat and provided with no groove. Each compound was introduced into the reactor with N₂ gas serving as carrier gas. The reactor was purged with N₂ gas serving as purge gas. O₃ was introduced as an oxygen source into the reactor. The reactor was purged with N₂ gas serving as purge gas. For TMS-pyrazole, the time for the first introduction step was set to 3 seconds, 11.7 seconds, 21.9 seconds, 80.2 seconds, and 282.9 seconds, and each step was performed 100 cycles under the conditions shown in Table 2 below. For TMS-imidazole, the time for the first introduction step was set to 15.2 seconds, 90 seconds, 223.5 seconds, 364.6 seconds, and 104 seconds, and each step was performed 100 cycles under the conditions shown in Table 2 below.

TABLE 2

| | temperature | pressure | time | flow rate |
|---|---|---|---|---|
| | (°C) | (Pa) | (sec) | (sccm) |
| first introduction step | 650 | 100 | — | 50*¹ |
| first purge step | 650 | 100 | 12 | 200 |
| second introduction step | 650 | 130 | 20 | 200 |
| second purge step | 650 | 100 | 12 | 200 |

*¹Flow rate of carrier gas

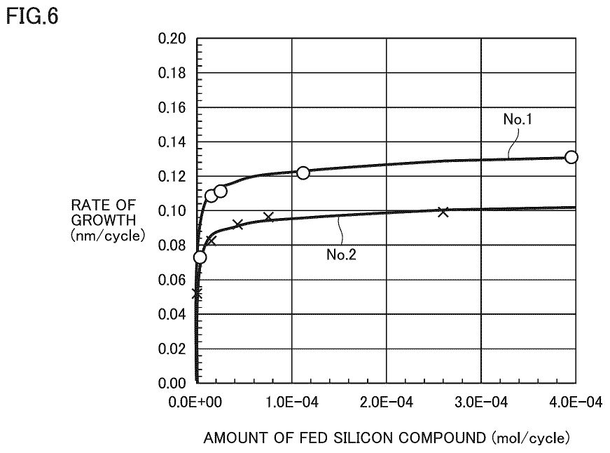

The rate of growth of the silicon oxide film of each of TMS-pyrazole and TMS-imidazole was calculated. The rate of growth represents a growth of the silicon oxide film with respect to the amount of the fed silicon compound, and serves as an indicator of ALD. While the amount of the fed compound increases, the rate of growth of the silicon oxide film reaches saturation and, at this time, the silicon oxide film is identified as being formed by ALD. The rate of growth was calculated from the amount of the film deposited per cycle. The results are shown in FIG. 6.

It has been confirmed, from the results shown in FIG. 6, the curve of the rate of growth becomes flat, i.e., reaches saturation, while the amount of each of the fed TMS-pyrazole and TMS-imidazole increases. It is accordingly seen that a silicon oxide film is formed by ALD from each of TMS-pyrazole and TMS-imidazole.

### Test Example 2

Silicon oxide films were deposited from the prepared TMS-pyrazole and TMS-imidazole by atomic layer deposition, similarly to Test Example 1, under conditions different from those of Test Example 1. Specifically, for TMS-pyrazole, the time for the first introduction step was set to 161.7 seconds, and the temperature for each step was set to 200° C., 300° C., 350° C., 500° C., 650° C., and 700° C. For TMS-imidazole, the time for the first introduction step was set to 37.9 seconds, and the temperature for each step was set to 200° C., 300° C., 400° C., 500° C., 650° C., and 700° C. The other conditions for this test are shown in Table 3 below. Each step was performed 100 cycles under these conditions.

TABLE 3

| | temperature | pressure | time | flow rate |
|---|---|---|---|---|
| | (°C) | (Pa) | (sec) | (sccm) |
| first introduction step | — | 100 | — | 50*¹ |
| first purge step | — | 100 | 12 | 200 |
| second introduction step | — | 130 | 20 | 200 |
| second purge step | — | 100 | 12 | 200 |

*¹Flow rate of carrier gas

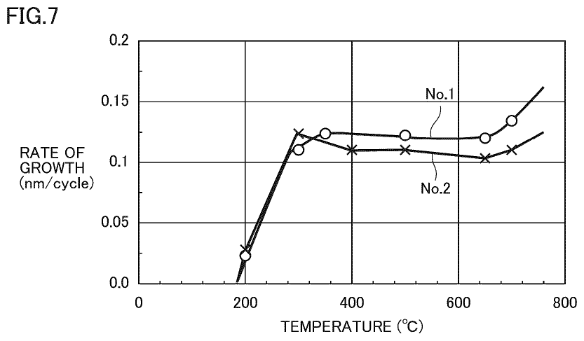

The thickness and Ra of the silicon oxide film of each of TMS-pyrazole and TMS-imidazole were measured by the XRR measurement apparatus as described above, to calculate the rate of growth. The conditions for XRR are those described above. The results are shown in Table 4 and FIG. 7.

TABLE 4

| | temperature | thickness | Ra | Ra | rate of growth |
|---|---|---|---|---|---|
| No. | (°C) | (nm) | (nm) | (%) | (nm/cycle) |
| 1 | 200 | 2.29 | 0.26 | 11.4 | 0.02 |
| | 300 | 11.01 | 0.25 | 2.3 | 0.11 |
| | 350 | 12.38 | 0.24 | 1.9 | 0.12 |
| | 500 | 12.23 | 0.37 | 3.0 | 0.12 |
| | 650 | 11.99 | 0.45 | 3.8 | 0.12 |
| | 700 | 13.43 | 0.46 | 3.4 | 0.13 |
| 2 | 200 | 0.30 | 0.42 | 140 | 0.03 |
| | 300 | 12.39 | 0.20 | 1.6 | 0.12 |
| | 400 | 11.30 | 0.15 | 1.3 | 0.11 |
| | 500 | 11.32 | 0.24 | 2.1 | 0.11 |
| | 650 | 10.59 | 0.40 | 3.8 | 0.10 |
| | 700 | 10.64 | 0.15 | 1.4 | 0.11 |

It is seen from the results shown in Table 4 and FIG. 7 that TMS-pyrazole and TMS-imidazole were both slower in the rate of growth at 200° C., relative to the rate of growth in other temperature ranges. Namely, it is considered difficult to deposit a silicon oxide film at 200° C. from each of TMS-pyrazole and TMS-imidazole. Moreover, for both of TMS-pyrazole and TMS-imidazole, Ra is 10% or less in each of all temperature ranges other than 200° C., from which it is seen that uniform silicon oxide films have been formed.

### Test Example 3

Silicon oxide films were deposited from the prepared TMS-pyrazole by atomic layer deposition, similarly to Test Example 1, under conditions different from those of Test Example 1. Specifically, as a substrate, a silicon substrate was used that was provided with a plurality of grooves (holes) each having a width of 150 nm and a depth of 3000 nm, and titanium nitride deposited in advance to about 15 nm on the surface of the substrate and the hole. The steps were each performed 296 cycles under the conditions shown in Table 5 below. In Table 5, in each of the first purge step and the second purge step, vacuum purging (“vacuum” in Table 5), purging with purge gas (“gas” in Table 5), purging with purge gas, vacuum purging, and purging with purge gas were performed in this order.

TABLE 5

| | | temperature | pressure | time | flow rate |
|---|---|---|---|---|---|
| | | (°C) | (Pa) | (sec) | (sccm) |
| first introduction step | | 650 | 560 | 80.2 | 50*¹ |
| first purge step | vacuum | 650 | — | 20 | — |
| | gas | | 13 | 12 | 200 |
| | gas | | 495 | 12 | 1000 |
| | vacuum | | — | 20 | — |
| | gas | | 13 | 12 | 200 |
| second introduction step | | 650 | 1380 | 20 | 200 |
| second purge | vacuum | 650 | — | 20 | — |
| step | gas | | 13 | 12 | 200 |
| | gas | | 495 | 12 | 1000 |
| | vacuum | | — | 20 | — |
| | gas | | 13 | 12 | 200 |

*¹Flow rate of carrier gas

The thickness of the silicon oxide film was calculated by cutting the substrate at any position in the direction perpendicular to the hole, performing FIB treatment, then imaging a cross section by the TEM as described above, and binarizing a resultant TEM image. Conditions for the TEM are those as described above. The sites where the silicon oxide film was measured were: an upper portion of the hole (from a depth of 0 nm to a depth of 1000 nm from the substrate surface), an intermediate portion (from a depth of 1000 nm to a depth of 2000 nm from the substrate surface), and a lower portion (from a distance of 0 nm to 1000 nm from the bottom wall surface of the hole). Respective photographs of the measurement sites are shown in Table 8.

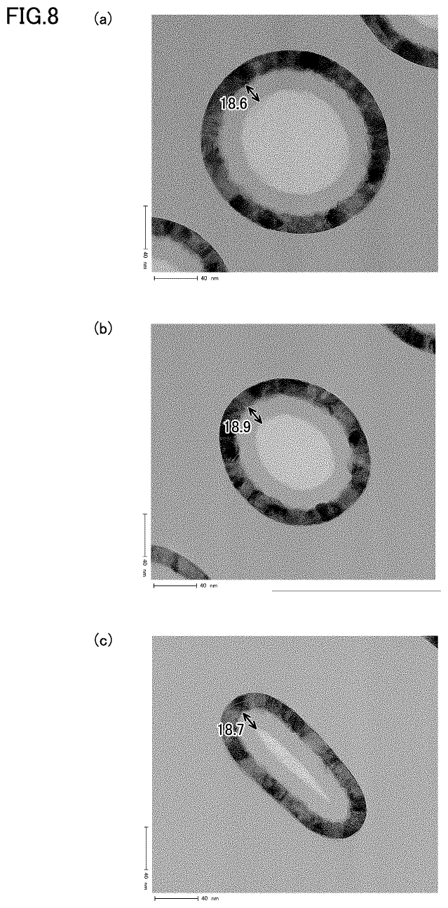

It is seen from FIG. 8 that the thickness of the silicon oxide film was: the upper portion (t₁): 18.6 nm, the intermediate portion (t₃): 18.9 nm, and the lower portion (t₂): 18.7 nm. These values were substituted into the left-hand sides of the above-indicated Formulas (i) to (iii) to determine solutions: Formula (i): 0.005, Formula (ii): 0.016, and Formula (iii): 0.011. It is seen from these results that the thickness difference is small in the upper portion, the intermediate portion, and the lower portion of the hole, i.e., the film thickness has high uniformity.

The measured thickness (t) of the silicon oxide film deposited on the flat portion of the substrate was 20.0 nm. This thickness and respective thicknesses in the upper portion, the intermediate portion, and the lower portion were substituted into the following Formula (iv) to confirm a relationship between the film thickness on the flat portion of the substrate and the film thicknesses in the hole.

|t−t_{1 to 3}/t≤0.2 Formula(iv)

Solutions to the formula are: Formula (iv): 0.07 for t₁, Formula (iv): 0.065 for t₂, and Formula (iv): 0.055 for t₃. It is seen from these results that there is a small difference between the film thickness on the flat portion of the substrate and each of respective film thicknesses in the portions of the hole, i.e., the film thickness has high uniformity.

Regarding the present example, it has been confirmed that TMS-imidazole is equivalent to TMS-pyrazole in terms of the value of MBDE, confirmed from the results of Test Example 1 that the silicon oxide film is formed by ALD, and confirmed from the results of Test Example 2 that the uniform silicon oxide film is formed on the flat substrate. It is therefore considered that a uniform silicon oxide film is formed as well from TMS-imidazole by atomic layer deposition on a substrate provided with a plurality of grooves, similar to the silicon oxide film formed from TMS-pyrazole.

Thus, the method for forming, by atomic layer deposition, a silicon oxide film having high uniformity from a silicon compound having high heat resistance in the present disclosure will be directly involved in innovation in semiconductor manufacturing, and can contribute to the smart society or a part of activities for sustainable development goals (SDGs), including electric vehicle and energy efficiency, that will spread more widely in the future.

It should be construed that the embodiments and examples disclosed herein are given by way of illustration in all respects, not by way of limitation. It is intended that the scope of the present invention is defined by claims, not by the description above, and encompasses all modifications and variations equivalent in meaning and scope to the claims.

### REFERENCE SIGNS LIST

1 substrate; 2 surface; 3 silicon oxide film; 4 groove; 5 sidewall surface; 6 bottom wall surface; 7 surface; 10 film deposition apparatus; 11 reactor; 12 precursor feeder; 13 carrier gas feed channel; 14 precursor gas feed channel; 15 purge gas feed channel; 16 oxygen source feed channel; 17 discharge channel; 18 APC valve; 19 needle valve; 20, 21, 22 on-off valve.

1. A method for forming a silicon oxide film, comprising:
a provision step of providing a substrate in a reactor;
a first introduction step of introducing, into the reactor, at least one silicon compound represented by the following Formula (1);
a first purge step of purging the reactor with purge gas;
a second introduction step of introducing an oxygen source into the reactor; and
a second purge step of purging the reactor with the purge gas, wherein
the first introduction step, the first purge step, the second introduction step, and the second purge step are performed repeatedly until silicon oxide having a desired thickness is deposited on a surface of the substrate,
the first introduction step, the first purge step, the second introduction step, and the second purge step are performed at a temperature of 300° C. or more and 800° C. or less and a pressure of 7.6 Pa or more and 100 kPa or less, and
an average roughness of the thickness of the silicon oxide film thus formed is 10% or less with respect to the thickness of the silicon oxide film thus formed: 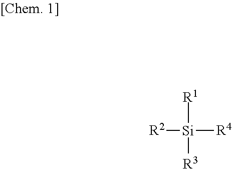
in the Formula (1),
R¹ and R² are each independently a methyl group or an ethyl group,
R³ is a methyl group, an ethyl group, a group represented by the following Formula (2), or a group represented by the following Formula (3), and
R⁴ is a group represented by the following Formula (2), or a group represented by the following Formula (3): 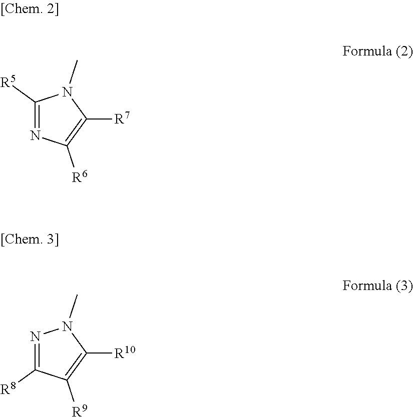
in the Formula (2) and the Formula (3), R⁵ to R¹⁰ are each independently a hydrogen atom, a methyl group, or an ethyl group.

2. A method for forming a silicon oxide film, comprising:
a provision step of providing, in a reactor, a substrate having a surface provided with a groove;
a first introduction step of introducing, into the reactor, at least one silicon compound represented by the following Formula (1);
a first purge step of purging the reactor with purge gas;
a second introduction step of introducing an oxygen source into the reactor; and
a second purge step of purging the reactor with the purge gas, wherein
the first introduction step, the first purge step, the second introduction step, and the second purge step are performed repeatedly until silicon oxide having a desired thickness is deposited on the surface of the substrate,
the first introduction step, the first purge step, the second introduction step, and the second purge step are performed at a temperature of 300° C. or more and 800° C. or less and a pressure of 7.6 Pa or more and 100 kPa or less, and
the silicon oxide film satisfies a relationship defined by Formula (i):

|t₁−t₂|/t₁≤0.2
in the Formula (i),
t₁ represents a thickness of the silicon oxide film (nm) in an upper portion of the groove, and
t₂ represents a thickness of the silicon oxide film (nm) in a lower portion of the groove: 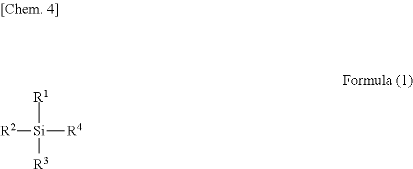
in the Formula (1),
R¹ and R² are each independently a methyl group or an ethyl group,
R³ is a methyl group, an ethyl group, a group represented by the following Formula (2), or a group represented by the following Formula (3), and
R⁴ is a group represented by the following Formula (2), or a group represented by the following Formula (3): 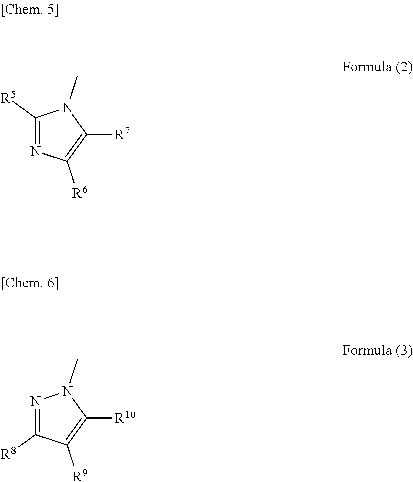
in the Formula (2) and the Formula (3), R⁵ to R¹⁰ are each independently a hydrogen atom, a methyl group, or an ethyl group.

3. The method for forming a silicon oxide film according to claim 1, wherein
in the Formula (1),
R¹ and R² are each a methyl group,
R³ is a methyl group, or a group represented by the Formula (3), and
R⁴ is a group represented by the Formula (3),
where R⁸ to R¹⁰ are each independently a hydrogen atom, a methyl group, or an ethyl group.

4. The method for forming a silicon oxide film according to claim 1, wherein
in the Formula (1),
R¹ to R³ are each a methyl group, and
R⁴ is a group represented by the Formula (3),
where R⁸ to R¹⁰ are each a hydrogen atom.

5. The method for forming a silicon oxide film according to claim 1, wherein
in the Formula (1),
R¹ and R² are each a methyl group, and
R³ and R⁴ are each a group represented by the Formula (2),
where R⁵ to R⁷ are each independently a hydrogen atom, a methyl group, or an ethyl group.

6. The method for forming a silicon oxide film according to claim 1, wherein
in the Formula (1),
R¹ to R³ are each a methyl group, and
R⁴ is a group represented by the Formula (2),
where R⁵ to R⁷ are each a hydrogen atom.

7. The method for forming a silicon oxide film according to claim 2, wherein
in the Formula (1),
R¹ and R² are each a methyl group,
R³ is a methyl group, or a group represented by the Formula (3), and
R⁴ is a group represented by the Formula (3),
where R⁸ to R¹⁰ are each independently a hydrogen atom, a methyl group, or an ethyl group.

8. The method for forming a silicon oxide film according to claim 2, wherein
in the Formula (1),
R¹ to R³ are each a methyl group, and
R⁴ is a group represented by the Formula (3),
where R⁸ to R¹⁰ are each a hydrogen atom.

9. The method for forming a silicon oxide film according to claim 2, wherein
in the Formula (1),
R¹ and R² are each a methyl group, and
R³ and R⁴ are each a group represented by the Formula (2),
where R⁵ to R⁷ are each independently a hydrogen atom, a methyl group, or an ethyl group.

10. The method for forming a silicon oxide film according to claim 2, wherein
in the Formula (1),
R¹ to R³ are each a methyl group, and
R⁴ is a group represented by the Formula (2),
where R⁵ to R⁷ are each a hydrogen atom.
